(19) United States
(12) Patent Application Publication
(10) Pub. No.: US 2025/0048736 A1
(43) Pub. Date: Feb. 6, 2025

(54) DISPLAY DEVICE

(71) Applicant: LG Display Co., Ltd., Seoul (KR)

(72) Inventors: Sumin LEE, Seoul (KR); ByungHyun LEE, Paju-si (KR); Daeyoung SEO, Seoul (KR); MinSeok KIM, Seoul (KR); TaeYong KIM, Anyang-si (KR)

(21) Appl. No.: 18/677,625

(22) Filed: May 29, 2024

(30) Foreign Application Priority Data
Jul. 31, 2023 (KR) 10-2023-0099347

(51) Int. Cl. H01L 27/12; H01L 25/16; H01L 33/62

(52) U.S. Cl. CPC H01L 27/124; H01L 25/167; H01L 33/62

(57) ABSTRACT

A display device is disclosed. An example display device according to an embodiment of the present disclosure includes a substrate configured to define a plurality of pixel areas disposed to be spaced apart from each other. The device includes a plurality of transmissive areas disposed between the plurality of pixel areas. The device includes a plurality of pixels disposed in the plurality of pixel areas and each including a plurality of sub pixels. The device includes a plurality of repair lines disposed between the plurality of sub pixels and made of a transparent conductive material, in which the plurality of repair lines is disposed on the same layer and spaced apart from each other. Therefore, the repair lines, which are used to repair the plurality of sub pixels when the plurality of sub pixels is defective, may be formed as a single-layer structure made of a transparent conductive material.

### CROSS-REFERENCE TO RELATED APPLICATIONS

This application claims the priority of Korean Patent Application No. 10-2023-0099347 filed on Jul. 31, 2023, in the Korean Intellectual Property Office, the disclosure of which is incorporated herein by reference.

### BACKGROUND

### Technical Field

The present disclosure relates to a transparent display device, and more particularly, to a transparent display device using a light emitting diode (LED).

### Description of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### BRIEF SUMMARY

Various embodiments of the present disclosure provide a transparent display device having a high transmittance rate.

Various embodiments of the present disclosure provide a display device in which an opaque line and a plurality of pixels are formed to overlap one another, thereby increasing or maximizing an area of a transmissive area.

Various embodiments of the present disclosure provide a display device in which a repair line for repairing a plurality of sub pixels, thereby improving quality.

Various embodiments of the present disclosure provide a display device in which a repair line is configured as a single-layer structure made of a transparent conductive material, thereby simplifying the structure of the repair line.

Various embodiments of the present disclosure provide a display device in which a repair line is made of only a transparent conductive material, thereby reducing or minimizing a decrease in transmittance rate of a transmissive area.

Various embodiments of the present disclosure provide a display device in which a plurality of sub pixels is disposed to be symmetric horizontally, such that a plurality of repair lines is disposed so as not to overlap one another.

Various embodiments of the present disclosure provide a display device in which a plurality of repair lines is disposed so as not to overlap one another when seen from a plan view, such that a plurality of repair lines is formed as a single layer on the same layer.

Various embodiments of the present disclosure provide a display device in which a plurality of repair lines and a first connection electrode are disposed together in a welding area to which laser beams are emitted during a process of repairing a sub pixel, thereby improving a yield of a repair process.

Various embodiments of the present disclosure provide a display device in which a repair line is disposed in the same pixel area or two adjacent pixel areas in consideration of a distance between a plurality of sub pixels, thereby reducing or minimizing a length of the repair line.

Various embodiments of the present disclosure provide a display device in which a repair line is disposed to have a shortest length to connect a pair of adjacent sub pixels, such that the display device may operate with low power consumption.

The technical benefits of the present disclosure are not limited to the above-mentioned benefits, and other benefits, which are not mentioned above, can be clearly understood by those skilled in the art from the following descriptions.

A display device according to an embodiment of the present disclosure includes: a substrate configured to define a plurality of pixel areas disposed to be spaced apart from each other, and a plurality of transmissive areas disposed between the plurality of pixel areas; a plurality of pixels disposed in the plurality of pixel areas and each including a plurality of sub pixels; and a plurality of repair lines disposed between the plurality of sub pixels and made of a transparent conductive material, in which the plurality of repair lines is disposed on the same layer and spaced apart from each other. Therefore, the repair lines, which are used to repair the plurality of sub pixels when the plurality of sub pixels are defective, may be formed as a single-layer structure made of a transparent conductive material, thereby simplifying the structure of the repair line and reducing or minimizing a decrease in transmittance rate of the transmissive area.

Other detailed matters of the exemplary embodiments are included in the detailed description and the drawings.

According to the present disclosure, it is possible to implement the transparent display device with the improved transmittance rate.

According to the present disclosure, the opaque components may be disposed to overlap one another, among the components of the display device, thereby ensuring the maximum area of the transmissive area of the display device.

According to the present disclosure, the opaque line and the plurality of pixels may be formed to overlap one another, thereby increasing an area of the transmissive area.

According to the present disclosure, the repair line may be formed to repair the plurality of sub pixels, thereby improving the yield of the display device.

According to the present disclosure, the repair line may be configured as the single-layer structure made of a transparent conductive material, thereby simplifying the structure of the repair line.

According to the present disclosure, the repair line may be made of only a transparent conductive material, thereby reducing or minimizing the decrease in transmittance rate of the transmissive area.

According to the present disclosure, the plurality of sub pixels is disposed to be symmetric horizontally, such that the plurality of repair lines does not overlap one another.

According to the present disclosure, the plurality of repair lines is disposed so as not to overlap one another, such that the plurality of repair lines may be formed as a single layer on the same layer.

According to the present disclosure, the plurality of repair lines and the first connection electrode may be disposed together in the welding area to which laser beams are emitted during the process of repairing the sub pixel, thereby improving the yield of the repair process.

According to the present disclosure, the repair line may be disposed in the same pixel area or two adjacent pixel areas in consideration of the distance between the plurality of sub pixels, thereby reducing the length of the repair line.

According to the present disclosure, the repair line may be disposed to have a shortest length to connect the pair of adjacent sub pixels, thereby reducing resistance of the repair line and operating the display device with low power consumption.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present disclosure;

FIG. 2A is a partial cross-sectional view of the display device according to the embodiment of the present disclosure;

FIG. 2B is a perspective view of a tiling display device according to the embodiment of the present disclosure;

FIG. 3 is a schematic enlarged top plan view of a display area of the display device according to the embodiment of the present disclosure;

FIG. 4 is an enlarged top plan view of area A in FIG. 3;

FIGS. 5A and 5B are cross-sectional views of sub pixels of the display device according to the embodiment of the present disclosure;

FIG. 6 is a cross-sectional view of a pair of sub pixels of the display device according to the embodiment of the present disclosure;

FIG. 7 is a schematic enlarged top plan view of a display area of a display device according to another embodiment of the present disclosure;

FIG. 8 is an enlarged top plan view of area B in FIG. 7;

FIG. 9 is a cross-sectional view of a pair of sub pixels of the display device according to another embodiment of the present disclosure;

FIG. 10 is an enlarged top plan view of a display device according to still another embodiment of the present disclosure;

FIGS. 11A and 11B are cross-sectional views of sub pixels of the display device according to still another embodiment of the present disclosure;

FIG. 12 is a schematic enlarged top plan view of the display device according to yet another embodiment of the present disclosure;

FIG. 13 is an enlarged top plan view of area C in FIG. 12; and

FIG. 14 is an enlarged top plan view of area D in FIG. 12.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

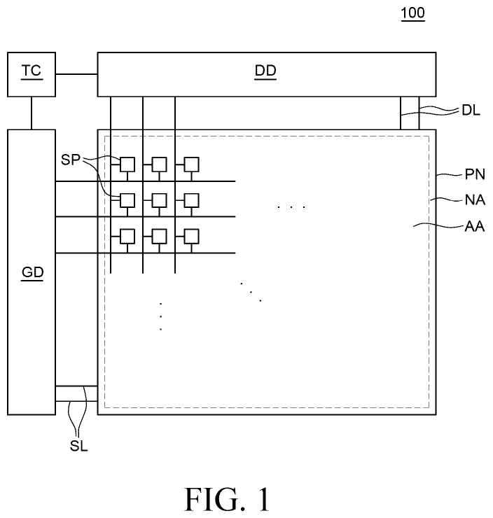

FIG. 1 is a schematic configuration view of a display device according to an embodiment of the present disclosure. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of sub pixels SP, the gate drive part GD configured to supply various types of signals to the display panel PN, and the timing controller TC configured to control the gate drive part GD, and the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number and arrangement of the gate drive part GD are not limited thereto.

The data drive part DD supplies data voltages to a plurality of data lines DL in response to a plurality of data control signals and image data provided from the timing controller TC. The data drive part DD may convert image data into data voltages by using a reference gamma voltage and supply the converted data voltages to the plurality of data lines DL.

The timing controller TC aligns image data, which are inputted from the outside, and supplies the image data to the data drive part DD. The timing controller TC may generate the gate control signals and the data control signals by using synchronizing signals, e.g., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of sub pixels SP. In the display panel PN, the plurality of scan lines SL and the plurality of data lines DL may intersect one another, and the plurality of sub pixels SP may be formed at intersection points between the scan line SL and the data line DL.

A display area AA and a non-display area NA may be defined on the display panel PN.

The display area AA is an area of the display device 100 in which images are displayed. The display area AA may include the plurality of sub pixels SP constituting a plurality of pixels PX, and a pixel circuit configured to operate the plurality of sub pixels SP. The plurality of sub pixels SP is minimum units that constitute the display area AA. The n sub pixels SP may constitute a single pixel PX. Thin-film transistors and the like for operating a plurality of light-emitting elements 120 may be respectively disposed in the plurality of sub pixels SP. The plurality of light emitting elements 120 may be differently defined depending on the type of display panel PN. For example, in case that the display panel PN is an inorganic light-emitting display panel PN, the light-emitting element 120 may be a light-emitting diode (LED) or a micro light-emitting diode (micro LED).

A plurality of signal lines for transmitting various types of signals to the plurality of sub pixels SP is disposed in the display area AA. For example, the plurality of signal lines may include the plurality of data lines DL for supplying data voltages to the plurality of sub pixels SP, and the plurality of scan lines SL for supplying scan signals to the plurality of sub pixels SP. The plurality of scan lines SL may extend in one direction in the display area AA and be connected to the plurality of sub pixels SP. The plurality of data lines DL may extend in a direction different from one direction in the display area AA and be connected to the plurality of sub pixels SP. In addition, a low-potential power line VSS, a high-potential power line VDD, and the like may be further disposed in the display area AA. However, the present disclosure is not limited thereto.

The non-display area NA may be defined as an area in which no image is displayed, e.g., an area extending from the display area AA. The non-display area NA may include link lines and pad electrodes for transmitting signals to the sub pixels SP in the display area AA. Alternatively, the non-display area NA may include drive ICs such as gate drivers IC and data drivers IC.

Meanwhile, the non-display area NA may be positioned on a rear surface of the display panel PN, e.g., a surface on which the sub pixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of sub pixels SP by a gate-in-active area (GIA) method in the display area AA.

For example, the data drive part DD and the timing controller TC may be formed on a separate flexible film and a printed circuit board and electrically connect the display panel PN, the data drive part DD, and the timing controller TC by a method of bonding the flexible film and the printed circuit board to a pad electrode formed in the non-display area NA of the display panel PN.

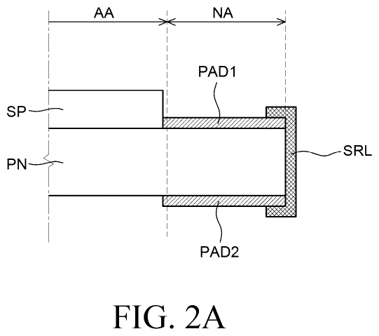

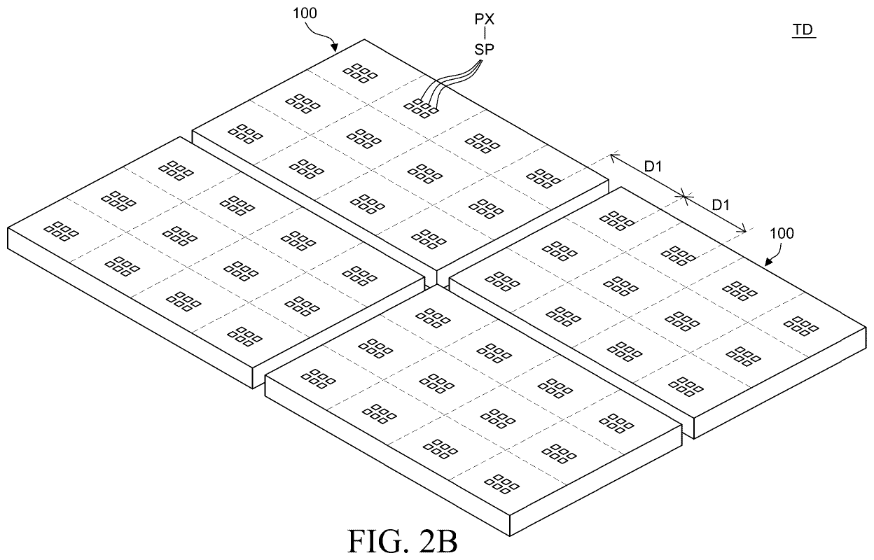

As another example, in case that the gate drive part GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to reduce or minimize the non-display area NA on the front surface of the display panel PN. Therefore, in case that the gate drive part GD, the data drive part DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to the embodiment of the present disclosure. FIG. 2B is a perspective view of a tiling display device according to the embodiment of the present disclosure.

A plurality of pad electrodes for transmitting various types of signals to the plurality of sub pixels SP is disposed in the non-display area NA of the display panel PN. For example, a first pad electrode PAD1 configured to transmit signals to the plurality of sub pixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of sub pixels SP may extend from the display area AA to the non-display area NA and be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of sub pixels SP through the second pad electrode PAD2, the side line SRL, and the first pad electrode PAD1. Therefore, the drive component is disposed on the rear surface of the display panel PN, and a signal transmission route is defined between the front and rear surfaces of the display panel PN, which may reduce or minimize an area of the non-display area NA on the front surface of the display panel PN.

Further, with reference to FIG. 2B, a tiling display device TD having a large screen may be implemented by connecting a plurality of display devices 100. In this case, as illustrated in FIG. 2A, in case that the tiling display device TD is implemented by using the display device 100 with the reduced or minimized bezel, a seam area in which no image is displayed between the display devices 100 may be reduced or minimized, thereby improving display quality.

For example, the plurality of sub pixels SP may constitute a single pixel PX. An interval DI between an outermost peripheral pixel PX of one display device 100 and an outermost peripheral pixel PX of another display device 100 adjacent to one display device 100 may be implemented to be equal to the interval DI between the pixels PX in one display device 100. Therefore, the seam area may be reduced or minimized as a constant interval of the pixels PX is implemented between the display device 100 and the display device 100.

However, as illustrated in FIG. 2A and FIG. 2B, the display device 100 according to the embodiment of the present disclosure may be a general display device in which the bezel is present. However, the present disclosure is not limited thereto.

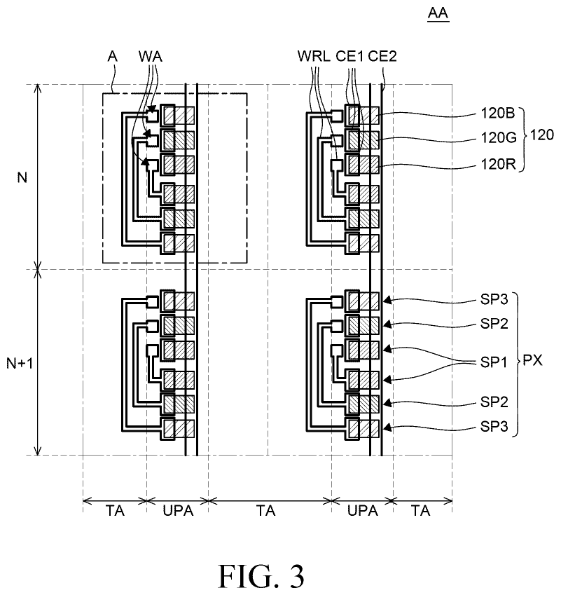

Hereinafter, the display panel PN of the display device 100 according to the embodiment of the present disclosure will be more specifically described with reference to FIGS. 3 to 6.

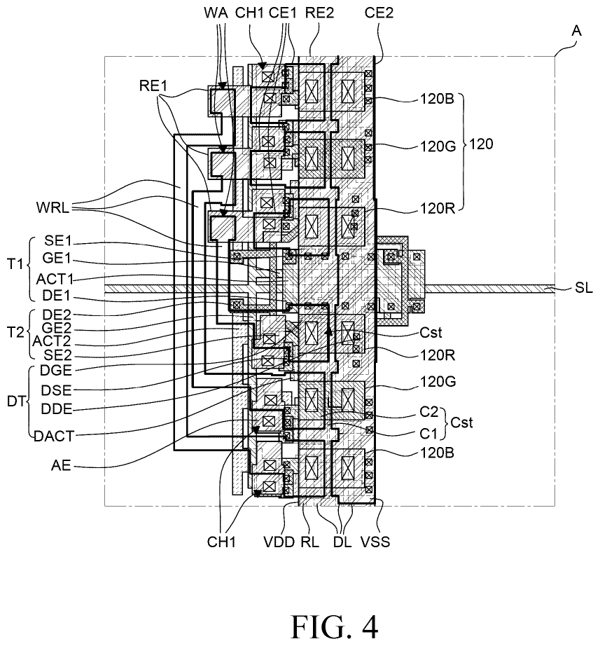

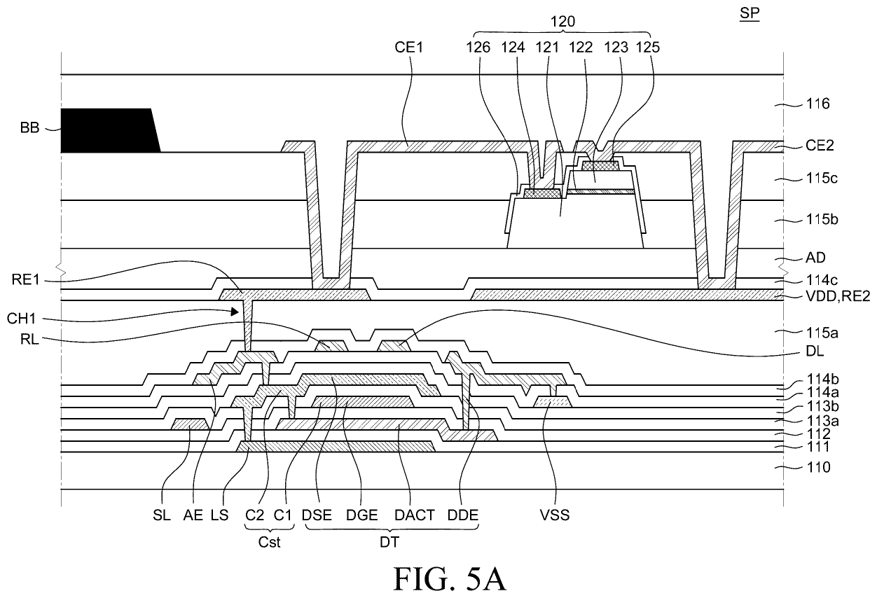

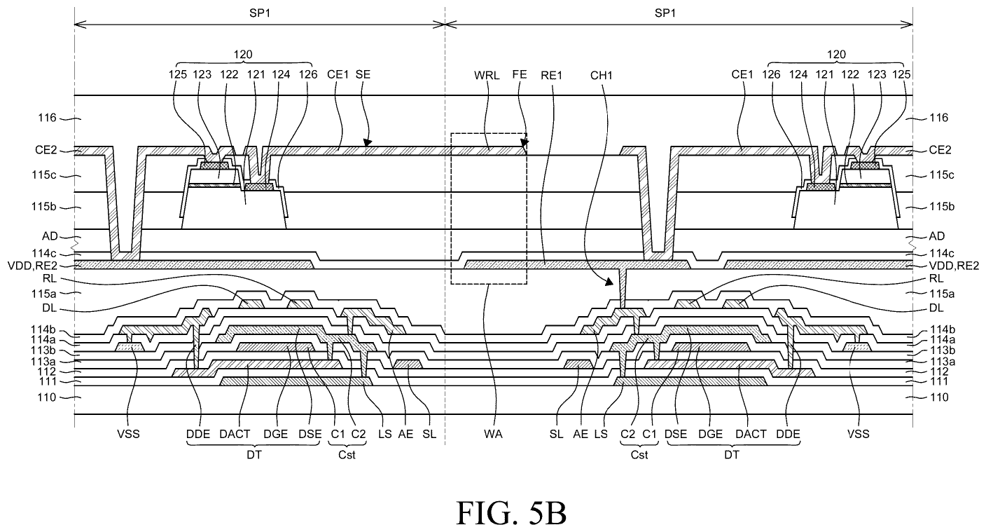

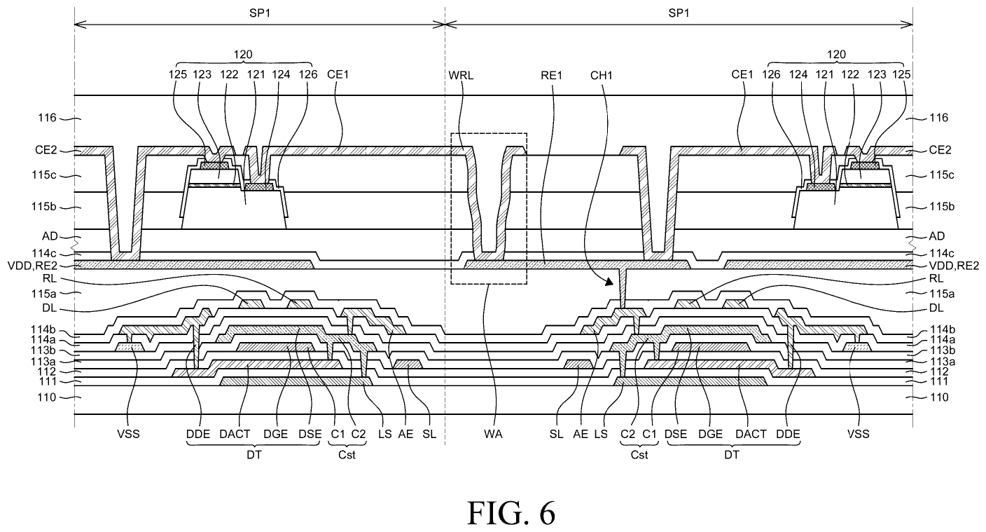

FIG. 3 is a schematic enlarged top plan view of the display area of the display device according to the embodiment of the present disclosure. FIG. 4 is an enlarged top plan view of area A in FIG. 3. FIGS. 5A and 5B are cross-sectional views of the sub pixels of the display device according to the embodiment of the present disclosure. FIG. 6 is a cross-sectional view of the pair of sub pixels of the display device according to the embodiment of the present disclosure. Specifically, FIG. 4 is an enlarged top plan view illustrating one pixel PX, and FIGS. 5A and 5B are cross-sectional views for explaining a specific structure of the sub pixel SP including a first contact hole CH1 and a repair line WRL for repair. FIG. 6 is a cross-sectional view of a pair of first sub pixels SP1 that has been completely repaired. For convenience of description, FIG. 3 illustrates only the plurality of light-emitting elements 120, the plurality of repair lines WRL, a plurality of first connection electrodes CE1, and a second connection electrode CE2. In FIG. 4, the first connection electrode CE1 and the second connection electrode CE2 are indicated by thick solid lines, and the hatching is omitted. Further, FIGS. 5B and 6 exemplarily illustrate a structure of the pair of first sub pixels SP1. A pair of second sub pixels SP2 and a pair of third sub pixels SP3 have substantially the same structure as the pair of first sub pixels SP1.

With reference to FIG. 3, the display area AA includes a plurality of pixel areas UPA and a plurality of transmissive areas TA.

The plurality of pixel areas UPA is formed in the display area AA. The plurality of pixel areas UPA are areas in which the pixels PX are disposed and images are displayed. The plurality of pixel areas UPA may be disposed to be spaced apart from each other with the plurality of transmissive areas TA interposed therebetween. For example, the plurality of pixel areas UPA may be disposed in a plurality of rows and a plurality of columns.

The plurality of sub pixels SP, which constitutes the pixel PX, is disposed in each of the plurality of pixel areas UPA. The plurality of sub pixels SP may each include the light-emitting element 120 and the pixel circuit and independently emit light. For example, the plurality of sub pixels SP may include the first sub pixels SP1, the second sub pixels SP2, and the third sub pixels SP3 that emit light beams with different colors. For example, the first sub pixel SP1 may be a red sub pixel, the second sub pixel SP2 may be a green sub pixel, and the third sub pixel SP3 may be a blue sub pixel. However, the present disclosure is not limited thereto.

Hereinafter, the description will be made on the assumption that one pixel PX includes two first sub pixels SP1, two second sub pixels SP2, and two third sub pixels SP3, e.g., two red sub pixels, two green sub pixels, and two blue sub pixels. However, the configuration of the pixel PX is not limited thereto.

The plurality of sub pixels SP, which constitutes one pixel PX, is disposed in a line in a column direction. The plurality of sub pixels SP may be disposed in the column direction and overlap a line extending in the column direction. For example, the plurality of sub pixels SP may overlap the data line DL, a reference line RL, the high-potential power line VDD, the low-potential power line VSS, and the like extending in the column direction. The pixel area UPA may be formed in an area in which a plurality of opaque lines is disposed, such that an area of the transmissive area TA may be ensured in the entire display area AA. The pixel area UPA, in which the plurality of sub pixels SP is disposed, may be an area that has a low transmittance rate and is substantially opaque because of the configurations of the pixel circuits, the light-emitting elements 120, and the like disposed in the plurality of sub pixels SP. Therefore, the plurality of sub pixels SP in the pixel area UPA may be disposed to overlap the opaque lines extending in the column direction, e.g., the data line DL, the reference line RL, the low-potential power line VSS, and the high-potential power line VDD. Therefore, the plurality of sub pixels SP in the pixel area UPA is disposed to overlap the plurality of lines, such that an area of the opaque area may be reduced in the entire display area AA, and a maximum area of the transmissive area TA may be ensured.

With reference to FIGS. 3 and 4 together, the pair of first sub pixels SP1, the pair of second sub pixels SP2, and the pair of third sub pixels SP3, which are included in one pixel PX, may be disposed to be symmetric horizontally with respect to the scan line SL. For example, one first sub pixel SP1 of the pair of first sub pixels SP1 may be disposed at one side of the scan line SL, and the other first sub pixel SP1 may be disposed at the other side of the scan line SL. One second sub pixel SP2 of the pair of second sub pixels SP2 may be disposed at one side of the scan line SL, and the other second sub pixel SP2 may be disposed at the other side of the scan line SL. Further, each of the pair of second sub pixels SP2 is disposed to be farther from the scan line SL than the first sub pixel SP1 from the scan line SL, such that the first sub pixel SP1 may be disposed between the second sub pixel SP2 and the scan line SL. Lastly, one third sub pixel SP3 of the pair of third sub pixels SP3 may be disposed at one side of the scan line SL, and the other third sub pixel SP3 may be disposed at the other side of the scan line SL. Further, each of the pair of third sub pixels SP3 may be disposed to be farther from the scan line SL than the second sub pixel SP2 from the scan line SL, such that the second sub pixel SP2 may be disposed between the third sub pixel SP3 and the first sub pixel SP1.

Therefore, a group of the first sub pixel SP1, the second sub pixel SP2, and the third sub pixel SP3 disposed at one side of the scan line SL and a group of the first sub pixel SP1, the second sub pixel SP2, and the third sub pixel SP3 disposed at the other side of the scan line SL may be disposed to be symmetric horizontally. For example, the plurality of sub pixels SP included in one pixel PX may be disposed in the order of the third sub pixel SP3, the second sub pixel SP2, the first sub pixel SP1, the first sub pixel SP1, the second sub pixel SP2, and the third sub pixel SP3. In the display device 100 according to the embodiment of the present disclosure, the groups of the first sub pixels SP1, the second sub pixels SP2, and the third sub pixels SP3, which are respectively disposed at one side and the other side of the scan line SL, are disposed to be symmetric horizontally, such that the repair lines WRL may be configured as a single-layer structure made of a transparent conductive material. A more detailed description will be described below with reference to FIGS. 5A to 6.

The plurality of transmissive areas TA are areas excluding the area in which the plurality of lines and the plurality of pixel areas UPA are disposed in the display area AA. The plurality of transmissive areas TA has a relatively high transmittance rate. The transmissive area TA transmits light, such that a background positioned on the rear surface of the display device 100 is visible from the front surface of the display device 100. The plurality of transmissive areas TA may be disposed to be spaced apart from each other with the plurality of lines and the plurality of pixel areas UPA interposed therebetween. The plurality of transmissive areas TA may be disposed to surround the plurality of pixel areas UPA. Therefore, the display device 100 according to the embodiment of the present disclosure may be implemented as the transparent display device 100 including the plurality of transmissive areas TA.

With reference to FIGS. 4 to 5B, the plurality of sub pixels SP each includes the pixel circuit and the light-emitting element 120. The pixel circuit may include a plurality of transistors T1, T2, and DT and a storage capacitor Cst and operate the light-emitting element 120. For example, the pixel circuit may include a first transistor T1, a second transistor T2, a driving transistor DT, and the storage capacitor Cst. Further, the plurality of sub pixels SP disposed in one pixel area UPA may be connected to the scan line SL, the plurality of data lines DL, the reference line RL, the high-potential power line VDD, and the low-potential power line VSS and supplied with various types of signals.

First, a substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

A light-blocking layer LS is disposed on each of the plurality of sub pixels SP on the substrate 110. The light-blocking layer LS blocks light entering a driving active layer DACT of the driving transistor DT, which will be described below, from a lower side of the substrate 110. The light-blocking layer LS may block light entering the driving active layer DACT of the driving transistor DT, thereby reducing or minimizing a leakage current.

A buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT, the first transistor T1, and the second transistor T2 are disposed in each of the plurality of sub pixels SP on the buffer layer 111.

The driving transistor DT, the first transistor T1, and the second transistor T2 of each of the plurality of sub pixels SP may be P-type thin-film transistors or N-type thin-film transistors. For example, in the P-type thin-film transistor, positive holes move from a source electrode to a drain electrode, such that current may flow from the source electrode to the drain electrode. In the N-type thin-film transistor, electrons move from a source electrode to a drain electrode, such that current may flow from the drain electrode to the source electrode. Hereinafter, the description will be made on the assumption that the driving transistor DT, the first transistor T1, and the second transistor T2 are the P-type thin-film transistors in which the current flows from the source electrodes to the drain electrodes. However, the present disclosure is not limited thereto.

First, the driving transistor DT is disposed in each of the plurality of sub pixels SP on the buffer layer 111. The driving transistor DT is a transistor for controlling a drive current to be supplied to the light-emitting element 120. In one pixel area UPA, the driving transistors DT of the plurality of sub pixels SP may be disposed in a line in the column direction. The plurality of driving transistors DT of the plurality of sub pixels SP may be disposed in a line while overlapping the areas in which the reference lines RL and the data lines DL are disposed.

The driving transistor DT includes the driving active layer DACT, a driving gate electrode DGE, a driving source electrode DSE, and a driving drain electrode DDE.

The driving active layer DACT is disposed on the buffer layer 111. The driving active layer DACT may be made of a semiconductor material such as an oxide semiconductor, amorphous silicon, or polysilicon. However, the present disclosure is not limited thereto.

A gate insulation layer 112 is disposed on the driving active layer DACT. The gate insulation layer 112 is an insulation layer for insulating the driving active layer DACT and the driving gate electrode DGE. The gate insulation layer 112 may be configured as a single layer or multilayer made of silicon oxide (SiOx) or silicon nitride (SiNx). However, the present disclosure is not limited thereto.

The driving gate electrode DGE is disposed on the gate insulation layer 112. The driving gate electrode DGE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first interlayer insulation layer 113a is disposed on the driving gate electrode DGE. A contact hole, through which the driving source electrode DSE is connected to the driving active layer DACT, is formed in the first interlayer insulation layer 113a. The first interlayer insulation layer 113a is an insulation layer for protecting components disposed below the first interlayer insulation layer 113a. The first interlayer insulation layer 113a may be configured as a single layer or multilayer made of silicon oxide (SiOx) or silicon nitride (SiNx). However, the present disclosure is not limited thereto.

The driving source electrode DSE is disposed on the first interlayer insulation layer 113a. The driving source electrode DSE is electrically connected to the driving active layer DACT through contact holes formed in the first interlayer insulation layer 113a and the gate insulation layer 112. Further, the driving source electrode DSE may be electrically connected to the second transistor T2. The driving source electrode DSE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A second interlayer insulation layer 113b and a first passivation layer 114a are disposed on the first interlayer insulation layer 113a, and the driving drain electrode DDE is disposed on the first passivation layer 114a. The driving drain electrode DDE is electrically connected to the driving active layer DACT through contact holes formed in the first passivation layer 114a, the second interlayer insulation layer 113b, the first interlayer insulation layer 113a, and the gate insulation layer 112. Further, the driving drain electrode DDE may be electrically connected to the low-potential power line VSS through a contact hole formed in the first passivation layer 114a. The driving drain electrode DDE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, the first transistor T1 is disposed in each of the plurality of sub pixels SP on the buffer layer 111. The first transistor T1 may be a transistor configured to transmit a data voltage to the driving gate electrode DGE of the driving transistor DT. The first transistor T1 may be referred to as a switching transistor. In this case, in one pixel area UPA, the plurality of first transistors T1 of the plurality of sub pixels SP may be disposed in a line in a row direction while overlapping the scan line SL.

Specifically, the scan line SL may extend in the row direction on the gate insulation layer 112 and be disposed to traverse the plurality of pixel areas UPA. Further, from the left side, the first transistor T1 of the first sub pixel SP1 at the other side of the scan line SL, the first transistor T1 of the first sub pixel SP1 at one side of the scan line SL, the first transistor T1 of the second sub pixel SP2 at the other side of the scan line SL, the first transistor T1 of the second sub pixel SP2 at one side of the scan line SL, the first transistor T1 of the third sub pixel SP3 at the other side of the scan line SL, and the first transistor T1 of the third sub pixel SP3 at one side of the scan line SL may be sequentially disposed.

In this case, the first transistors T1 of the pair of first sub pixels SP1 may be disposed adjacent to each other and share one data line DL. Further, the first transistors T1 of the pair of second sub pixels SP2 may also be disposed adjacent to each other and share one data line DL. Lastly, the first transistors T1 of the pair of third sub pixels SP3 may also be disposed adjacent to each other and share one data line DL.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be made of a semiconductor material such as an oxide semiconductor, amorphous silicon, or polysilicon. However, the present disclosure is not limited thereto.

The first gate electrode GE1 is disposed on the gate insulation layer 112. The first gate electrode GE1 may be electrically connected to the scan line SL. For example, the first gate electrode GE1 may be integrated with the scan line SL. The first gate electrode GE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first drain electrode DE1 is disposed on the first interlayer insulation layer 113a. The first drain electrode DE1 is electrically connected to the first active layer ACT1 through contact holes formed in the first interlayer insulation layer 113a and the gate insulation layer 112. Further, the first drain electrode DE1 may also be electrically connected to a second gate electrode GE2 of the second transistor T2 through the contact hole of the first interlayer insulation layer 113a. The first drain electrode DE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second interlayer insulation layer 113b is disposed on the first drain electrode DE1. The second interlayer insulation layer 113b is an insulation layer for protecting components disposed below the second interlayer insulation layer 113b. The second interlayer insulation layer 113b may be configured as a single layer or multilayer made of silicon oxide (SiOx) or silicon nitride (SiNx). However, the present disclosure is not limited thereto.

The first passivation layer 114a is disposed on the second interlayer insulation layer 113b. The first passivation layer 114a is an insulation layer for protecting components disposed below the first passivation layer 114a. The first passivation layer 114a may be configured as a single layer or multilayer made of silicon oxide (SiOx) or silicon nitride (SiNx). However, the present disclosure is not limited thereto.

The first source electrode SE1 is disposed on the first passivation layer 114a. The first source electrode SE1 is electrically connected to the first active layer ACT1 through the contact holes of the first passivation layer 114a, the second interlayer insulation layer 113b, and the first interlayer insulation layer 113a. Further, the first source electrode SE1 may be electrically connected to the data line DL. For example, the first source electrode SE1 may be integrated with the data line DL. The first source electrode SE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, the second transistor T2 is disposed in each of the plurality of sub pixels SP on the buffer layer 111. The second transistor T2 may be a transistor configured to compensate for a threshold voltage of the driving transistor DT. The second transistor T2 may be referred to as a sensing transistor. The second transistors T2 of the plurality of sub pixels SP may be respectively disposed at the left sides of the plurality of sub pixels SP and disposed in a line in the column direction.

For example, the scan line SL may include a portion protruding in the column direction from a portion extending in the row direction. A part of the scan line SL, which protrudes in the column direction, may be disposed adjacent to the left sides of the plurality of sub pixels SP and overlap the plurality of second transistors T2. The part of the scan line SL, which protrudes in the column direction, may serve as the second gate electrode GE2 of the second transistor T2 of the plurality of sub pixels SP. Therefore, the second transistors T2 of the plurality of sub pixels SP may be disposed on the protruding part of the scan line SL and disposed in a line in the column direction.

The second transistor T2 includes a second active layer ACT2, the second gate electrode GE2, a second source electrode SE2, and a second drain electrode DE2.

The second active layer ACT2 is disposed between the buffer layer 111 and the gate insulation layer 112. The second active layer ACT2 may be made of a semiconductor material such as an oxide semiconductor, amorphous silicon, or polysilicon. However, the present disclosure is not limited thereto.

In this case, the second active layers ACT2 of the plurality of adjacent sub pixels SP may be connected to one another. For example, the second active layers ACT2 of the first sub pixel SP1, the second sub pixel SP2, and the third sub pixel SP3 disposed at one side of the scan line SL may extend in the column direction and be connected to one another, and the second active layers ACT2 may be connected together to the second drain electrode DE2 disposed in the first sub pixel SP1. Further, the second active layers ACT2 of the first sub pixel SP1, the second sub pixel SP2, and the third sub pixel SP3 disposed at the other side of the scan line SL may also extend in the column direction and be connected to one another, and the second active layers ACT2 may be connected together to the second drain electrode DE2 disposed in the first sub pixel SP1.

That is, connection parts for connecting the reference line RL and channel areas of the second active layers ACT2 of the plurality of sub pixels SP are made of the transparent material of the second active layer ACT2, instead of an opaque electrically conductive material, such that a transmittance rate may be increased at an outermost periphery of the pixel area UPA. In addition, the connection parts for connecting the reference line RL and the channel areas of the second active layers ACT2 of the plurality of sub pixels SP are made of the material of the second active layer ACT2, such that the contact hole may be eliminated, and the structure of the pixel area UPA may be simplified.

The second gate electrode GE2 is disposed between the gate insulation layer 112 and the first interlayer insulation layer 113a. The second gate electrode GE2 may be electrically connected to the scan line SL. For example, the second gate electrode GE2 may be integrated with the protruding part of the scan line SL and electrically connected to the protruding part of the scan line SL. The second gate electrode GE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second source electrode SE2 is disposed between the first interlayer insulation layer 113a and the second interlayer insulation layer 113b. The second source electrode SE2 is electrically connected to the second active layer ACT2 through the contact holes of the first interlayer insulation layer 113a and the gate insulation layer 112. Further, the second source electrode SE2 may be electrically connected to the driving source electrode DSE. The second source electrode SE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second drain electrode DE2 is disposed between the first passivation layer 114a and a second passivation layer 114b. The second drain electrode DE2 is electrically connected to the second active layer ACT2 through contact holes formed in the first passivation layer 114a, the second interlayer insulation layer 113b, the first interlayer insulation layer 113a, and the gate insulation layer 112. The second drain electrode DE2 may be integrated with the reference line RL and electrically connected to the reference line RL. The second drain electrode DE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, the storage capacitor Cst is disposed on the gate insulation layer 112. The storage capacitor Cst may store a potential difference between the driving gate electrode DGE and the driving source electrode DSE of the driving transistor DT while the light-emitting element 120 emits light, such that a constant drive current may be supplied to the light-emitting element 120. The storage capacitor Cst may include a first capacitor electrode C1 electrically connected to the driving gate electrode DGE, and a second capacitor electrode C2 electrically connected to the driving source electrode DSE. The storage capacitor Cst may maintain constant voltages of the driving gate electrode DGE and the driving source electrode DSE.

Specifically, the first capacitor electrode C1 is disposed on the gate insulation layer 112. The first capacitor electrode C1 may be integrated with the driving gate electrode DGE. The second capacitor electrode C2 is disposed on the first interlayer insulation layer 113a. The first capacitor electrode C1 and the second capacitor electrode C2 may be disposed to overlap each other with the first interlayer insulation layer 113a interposed therebetween. In this case, the second capacitor electrode C2 may be integrated with the driving source electrode DSE. The first capacitor electrode C1 and the second capacitor electrode C2 may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, an auxiliary electrode AE is disposed on the first passivation layer 114a. The auxiliary electrode AE is an electrode for electrically connecting the driving source electrode DSE and a first reflective electrode RE1. The driving source electrode DSE and the first reflective electrode RE1 may be electrically connected to each other through the auxiliary electrode AE. The auxiliary electrode AE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The low-potential power line VSS is disposed on the second interlayer insulation layer 113b. The low-potential power line VSS may be disposed in the column direction and overlap the plurality of pixel areas UPA. The low-potential power line VSS may be electrically connected to the driving drain electrode DDE. The low-potential power line VSS may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The reference line RL is disposed on the first passivation layer 114a. The reference line RL may be disposed in the column direction and overlap the plurality of pixel areas UPA. The reference line RL may be disposed adjacent to the plurality of second transistors T2 and electrically connected to the plurality of second transistors T2. The reference line RL may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The plurality of data lines DL is disposed on the first passivation layer 114a. The plurality of data lines DL may extend in the column direction and overlap the plurality of pixel areas UPA. The plurality of data lines DL may include the data line DL connected to the first transistors T1 of the plurality of first sub pixels SP1, the data line DL connected to the first transistors T1 of the plurality of second sub pixels SP2, and the data line DL connected to the first transistors T1 of the plurality of third sub pixels SP3. For example, from the left side, the reference line RL, the data line DL connected to the first sub pixel SP1, the data line DL connected to the second sub pixel SP2, and the data line DL connected to the third sub pixel SP3 may be sequentially disposed.

Next, the second passivation layer 114b is disposed on the driving transistor DT, the first transistor T1, the second transistor T2, the storage capacitor Cst, the reference line RL, and the data line DL. The second passivation layer 114b may be an insulation layer for protecting components disposed below the second passivation layer 114b. The second passivation layer 114b may be configured as a single layer or multilayer made of silicon oxide (SiOx) or silicon nitride (SiNx). However, the present disclosure is not limited thereto.

A first planarization layer 115a is disposed on the second passivation layer 114b. The first planarization layer 115a may planarize an upper portion of the substrate 110 on which the plurality of transistors and the storage capacitor Cst are disposed. The first planarization layer 115a may be configured as a single layer or multilayer and made of a photoresist or an acrylic-based organic material, for example. However, the present disclosure is not limited thereto.

Meanwhile, although not illustrated in the drawings, an additional passivation layer may be further disposed on the first planarization layer 115a. For example, the passivation layer, which is configured as a single layer or multilayer made of silicon oxide (SiOx) or silicon nitride (SiNx), may be disposed on the first planarization layer 115a and protect the components disposed below the passivation layer.

Next, the plurality of first reflective electrodes RE1 is disposed on the first planarization layer 115a. The plurality of first reflective electrodes RE1 may be respectively disposed in the plurality of sub pixels SP and electrically connect the driving transistors DT and the light-emitting elements 120. At the same time, the plurality of first reflective electrodes RE1 may reflect the light, which is emitted from the light-emitting elements 120, to the outside of the display device 100. The plurality of first reflective electrodes RE1 may be disposed adjacent to the driving source electrodes DSE in the plurality of sub pixels SP. The plurality of first reflective electrodes RE1 may be made of an opaque conductive material such as titanium (Ti), gold (Au), silver (Ag), copper (Cu), or an alloy thereof with high reflection efficiency. However, the present disclosure is not limited thereto.

Meanwhile, the first reflective electrode RE1 disposed in some of the plurality of sub pixels SP may overlap a welding area WA. A part of the first reflective electrode RE1, which is disposed in one first sub pixel SP1 of the pair of first sub pixels SP1, may protrude toward the welding area WA and overlap the repair line WRL. In the subsequent repair process, the first reflective electrode RE1 may be electrically and directly connected to the repair line WRL. A detailed description thereof will be described below with reference to FIG. 6.

A second reflective electrode RE2 or the high-potential power line VDD is disposed on the first planarization layer 115a. The second reflective electrode RE2 and the high-potential power line VDD may be integrated and configured to supply a high-potential power voltage to the light-emitting element 120 and reflect the light, which is emitted from the light-emitting element 120, to the outside of the display device 100. The second reflective electrodes RE2 of the plurality of sub pixels SP may be connected to and integrated with one another. The second reflective electrode RE2 and the high-potential power line VDD may extend in the column direction and be disposed to overlap the light-emitting element 120. The second reflective electrode RE2 and the high-potential power line VDD may be disposed to overlap the plurality of data lines DL, the reference line RL, and the low-potential power line VSS. The second reflective electrode RE2 and the high-potential power line VDD may be made of an opaque conductive material such as titanium (Ti), gold (Au), silver (Ag), copper (Cu), or an alloy thereof with high reflection efficiency. However, the present disclosure is not limited thereto.

A third passivation layer 114c is disposed on the plurality of first reflective electrodes RE1 and the second reflective electrode RE2. The third passivation layer 114c may be an insulation layer for protecting components disposed below the third passivation layer 114c. The third passivation layer 114c may be configured as a single layer or multilayer made of silicon oxide (SiOx) or silicon nitride (SiNx). However, the present disclosure is not limited thereto.

A bonding layer AD is disposed on the third passivation layer 114c. The bonding layer AD may be formed on the front surface of the substrate 110 and fix the light-emitting element 120 disposed on the bonding layer AD. The bonding layer AD may be made of a photocurable bonding material that may be cured by light. For example, the bonding layer AD may be made of any one material selected from adhesive polymer, epoxy resist, UV resin, a polyimide-based material, an acrylate-based material, an urethane-based material, and polydimethylsiloxane (PDMS). However, the present disclosure is not limited thereto.

The plurality of light-emitting elements 120 is provided on the bonding layer AD and disposed in each of the plurality of sub pixels SP. The light-emitting elements 120 may be elements configured to emit light by the current and include a red light-emitting element 120R configured to emit red light, a green light-emitting element 120G configured to emit green light, and a blue light-emitting element 120B configured to emit blue light. A combination of the light-emitting elements 120 may implement various colors including white. For example, the light-emitting element 120 may be a light-emitting diode (LED) or a micro LED. However, the present disclosure is not limited thereto.

The red light-emitting element 120R may be disposed in the first sub pixel SP1, the green light-emitting element 120G may be disposed in the second sub pixel SP2, and the blue light-emitting element 120B may be disposed in the third sub pixel SP3. The plurality of light-emitting elements 120 disposed in one pixel area UPA may be disposed in a line in the column direction. Further, the plurality of light-emitting elements 120 may be respectively disposed in the plurality of sub pixels SP and disposed to overlap the second reflective electrode RE2.

The plurality of light-emitting elements 120 each includes a first semiconductor layer 121, a light-emitting layer 122, a second semiconductor layer 123, a first electrode 124, a second electrode 125, and an encapsulation film 126.

The first semiconductor layer 121 is disposed on the bonding layer AD, and the second semiconductor layer 123 is disposed on the first semiconductor layer 121. The first semiconductor layer 121 and the second semiconductor layer 123 may each be a layer formed by doping a particular material with n-type and p-type impurities. For example, the first semiconductor layer 121 and the second semiconductor layer 123 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The light-emitting layer 122 is disposed between the first semiconductor layer 121 and the second semiconductor layer 123. The light-emitting layer 122 may emit light by receiving positive holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The first electrode 124 is disposed on the first semiconductor layer 121. The first electrode 124 is an electrode that electrically connects the driving transistor DT and the first semiconductor layer 121. In this case, the first semiconductor layer 121 may be a semiconductor layer doped with n-type impurities, and the first electrode 124 may be a cathode. The first electrode 124 may be disposed on a top surface of the first semiconductor layer 121 exposed from the light-emitting layer 122 and the second semiconductor layer 123. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 may be disposed on a top surface of the second semiconductor layer 123. The second electrode 125 is an electrode for electrically connecting the high-potential power line VDD and the second semiconductor layer 123. In this case, the second semiconductor layer 123 may be a semiconductor layer doped with p-type impurities, and the second electrode 125 may be an anode. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the encapsulation film 126 is disposed to surround the first semiconductor layer 121, the light-emitting layer 122, the second semiconductor layer 123, the first electrode 124, and the second electrode 125. The encapsulation film 126 may be made of an insulating material and protect the first semiconductor layer 121, the light-emitting layer 122, and the second semiconductor layer 123. Further, a contact hole, through which the first electrode 124 and the second electrode 125 are exposed, may be formed in the encapsulation film 126, such that the first connection electrode CE1, the second connection electrode CE2, the first electrode 124, and the second electrode 125 may be electrically connected.

Meanwhile, a part of a side surface of the first semiconductor layer 121 may be exposed from the encapsulation film 126. The light-emitting element 120 manufactured on a wafer may be separated from the wafer and transferred to the display panel PN. However, a part of the encapsulation film 126 may be torn during a process of separating the light-emitting element 120 from the wafer. For example, a part of the encapsulation film 126 adjacent to a lower edge of the first semiconductor layer 121 of the light-emitting element 120 may be torn during the process of separating the light-emitting element 120 from the wafer, such that a part of a lower side surface of the first semiconductor layer 121 may be exposed to the outside. Even though the lower portion of the light-emitting element 120 is exposed from the encapsulation film 126, the first connection electrode CE1 and the second connection electrode CE2 are formed after second and third planarization layers 115b and 115c, which cover the side surface of the first semiconductor layer 121, are formed, thereby reducing a short circuit defect.

Next, the second planarization layer 115b and the third planarization layer 115c are disposed on the bonding layer AD and the light-emitting element 120.

The second planarization layer 115b may partially overlap the side surfaces of the plurality of light-emitting elements 120 and fix and protect the plurality of light-emitting elements 120. The second planarization layer 115b may cover a torn portion of the encapsulation film 126 that protects the side surface of the first semiconductor layer 121 of the light-emitting element 120. Therefore, it is possible to suppress the contact between the connection electrode and the first semiconductor layer 121 and a short circuit defect later.

The third planarization layer 115c is formed to cover upper sides of the second planarization layer 115b and the light-emitting element 120. A contact hole, through which the first electrode 124 and the second electrode 125 of the light-emitting element 120 are exposed, may be formed in the third planarization layer 115c. The first electrode 124 and the second electrode 125 of the light-emitting element 120 may be exposed from the third planarization layer 115c. However, the third planarization layer 115c is partially disposed in an area between the first electrode 124 and the second electrode 125, thereby reducing a short circuit defect. The second planarization layer 115b and the third planarization layer 115c may each be configured as a single layer or multilayer and made of a photoresist or an acrylic-based organic material, for example. However, the present disclosure is not limited thereto.

The first connection electrode CE1 and the second connection electrode CE2 are disposed on the third planarization layer 115c.

The first connection electrode CE1 is an electrode that electrically connects the driving transistor DT and the first electrode 124 of the light-emitting element 120. The first connection electrode CE1 may be electrically connected to the first electrode 124, which is exposed from the third planarization layer 115c, and simultaneously electrically connected to the first reflective electrode RE1 through contact holes formed in the third planarization layer 115c, the second planarization layer 115b, and the third passivation layer 114c. Therefore, the first electrode 124 and the driving source electrode DSE may be electrically connected through the first connection electrode CE1, the first reflective electrode RE1, and the auxiliary electrode AE.

The second connection electrode CE2 is an electrode that electrically connects the high-potential power line VDD and the second electrode 125 of the light-emitting element 120. The second connection electrode CE2 may be electrically connected to the second electrode 125, which is exposed from the third planarization layer 115c, and electrically connected to the second reflective electrode RE2 or the high-potential power line VDD through contact holes formed in the third planarization layer 115c, the second planarization layer 115b, and the third passivation layer 114c. Therefore, the second electrode 125 and the high-potential power line VDD may be electrically connected through the second connection electrode CE2.

The first connection electrode CE1 and the second connection electrode CE2 may be made of a transparent conductive material such as indium tin oxide (ITO) or indium zinc oxide (IZO). However, the present disclosure is not limited thereto.

Meanwhile, the drawings illustrate that the driving source electrode DSE of the driving transistor DT and the first electrode 124 of the light-emitting element 120 are electrically connected. However, the driving drain electrode DDE of the driving transistor DT and the second electrode 125 of the light-emitting element 120 may be electrically connected in accordance with the type of the driving transistor DT and the design of the pixel circuit. However, the present disclosure is not limited thereto.

Next, a bank BB is disposed on the third planarization layer 115c, the first connection electrode CE1, and the second connection electrode CE2 in the pixel area UPA. The bank BB may be disposed to be spaced apart from the light-emitting element 120 at a predetermined interval. The bank BB may be disposed on a boundary between the plurality of sub pixels SP and partially cover the first connection electrode CE1 and the second connection electrode CE2. The bank BB may be disposed to be spaced apart from the transmissive area TA. The bank BB may be made of an opaque material, for example, black resin to reduce a color mixture between the plurality of sub pixels SP. However, the present disclosure is not limited thereto.

A protective layer 116 is disposed on the first connection electrode CE1, the second connection electrode CE2, and the bank BB. The protective layer 116 is a layer for protecting components disposed below the protective layer 116. The protective layer 116 may be configured as a single layer or multilayer made of benzocyclobutene, light transmissive epoxy, a photoresist, an acrylic-based organic material, or an inorganic material silicon oxide (SiOx) or silicon nitride (SiNx), for example. However, the present disclosure is not limited thereto.

Meanwhile, an illumination inspection process for detecting a defective sub pixel SP may be performed during a process of manufacturing the display device 100. For example, a defective sub pixel SP, which does not emit light, may be detected by operating the plurality of light-emitting elements 120 in the state in which the plurality of light-emitting elements 120, the first connection electrode CE1, and the second connection electrode CE2 are formed. For example, the defective sub pixel SP may be caused by a defect of the pixel circuit, a transfer defect of the light-emitting element 120, or foreign substances. Therefore, in the display device 100 according to the embodiment of the present disclosure, a process of repairing the defective sub pixel SP may be performed, thereby improving the quality of the display device 100.

Specifically, when a defect occurs on any one of the plurality of sub pixels SP, the repair line WRL may be used to connect the light-emitting element 120 of the defective sub pixel SP to a pixel circuit of a normal sub pixel SP, such that the light-emitting element 120 of the defective sub pixel SP may be operated by the pixel circuit of the normal sub pixel SP. Therefore, the plurality of repair lines WRL for repair is disposed in the display device 100.

With reference to FIGS. 3, 4, and 5B together, the plurality of repair lines WRL is disposed on the third planarization layers 115c in the plurality of pixel areas UPA. The plurality of repair lines WRL may be disposed to connect the same types of sub pixels SP. For example, the repair lines WRL may be respectively disposed between the pair of first sub pixels SP1, between the pair of second sub pixels SP2, and between the pair of third sub pixels SP3.

One end of the repair line WRL may be disposed to overlap the first reflective electrode RE1 of one of the pair of sub pixels SP, and the other end of the repair line WRL may be connected to the first connection electrode CE1 of the other of the pair of sub pixels SP. For example, one end FE of the repair line WRL may be disposed to overlap the first reflective electrode RE1 of the first sub pixel SP1 disposed at one side of the scan line SL, and the other end SE of the repair line WRL may be connected to the first connection electrode CE1 of the first sub pixel SP1 disposed at the other side of the scan line SL. In this case, the first connection electrode CE1 and the repair line WRL may be disposed on the same layer and integrated. For example, the repair line WRL may be continuously and contiguously extending from the first connection electrode CE1 and is disposed on a same layer (e.g., both the first connection electrode CE1 and the repair line WRL sit on the same layer, the third planarization layer 115c). The other end SE of the repair line WRL is continuously and contiguously connected to the first connection electrode CE1. Therefore, the repair line WRL may be connected to the first connection electrode CE1 of one of the pair of sub pixels SP without being connected to the first connection electrode CE1 of the other sub pixel SP, but instead, the repair line WRL may be disposed to overlap the first reflective electrode RE1 of the other sub pixel SP from a plan view. In some embodiments, the first connection electrode CE1 and the repair line WRL are of the same material and manufactured during the same process.

In this case, an area in which the first reflective electrode RE1 and the repair line WRL overlap each other from a plan view may be defined as the welding area WA that is irradiated with laser beams during the repair process. The first reflective electrode RE1 and the repair line WRL may be connected by irradiating the welding area WA with laser beams. A detailed description thereof will be described with reference to FIG. 6.

Next, with reference to FIGS. 5A and 6, when a defect occurs on any one of the plurality of sub pixels SP, the repair process may be performed by separating the pixel circuit of the defective sub pixel SP and the light-emitting element 120 and connecting the light-emitting element 120 of the defective sub pixel SP to the pixel circuit of the normal sub pixel SP.

First, the pixel circuit of the defective sub pixel SP and the light-emitting element 120 may be separated. If the defective sub pixel SP and the light-emitting element 120 are not electrically separated, a bright spot defect or the like may occur because the light-emitting elements 120 of some of the defective sub pixels SP abnormally operate. For example, the light-emitting element 120 of the defective sub pixel SP continuously emits light regardless of images, which may cause a defect in which a bright spot is recognized. Therefore, the pixel circuit of the defective sub pixel SP and the light-emitting element 120 may be separated so that the drive current is not supplied from the pixel circuit of the defective sub pixel SP to the light-emitting element 120.

In this case, a drive current transmission route between the light-emitting element 120 and the pixel circuit of the defective sub pixel SP may be eliminated by destroying the connection portion between the light-emitting element 120 and the driving source electrode DSE of the driving transistor DT. For example, the light-emitting element 120 and the driving transistor DT may be electrically connected to each other through the first reflective electrode RE1 and the first connection electrode CE1. Further, any one of the connection portions between the first reflective electrode RE1 and the first connection electrode CE1 may be destroyed by being irradiated with laser beams. For example, with reference to FIG. 5A, the first reflective electrode RE1 may include a portion, which overlaps the first connection electrode CE1, and a portion that does not overlap the first connection electrode CE1. The first reflective electrode RE1 and the driving transistor DT may be electrically connected through the first contact hole CH1 formed to correspond to the portion that does not overlap the first connection electrode CE1. That is, the first contact hole CH1 may overlap the first reflective electrode RE1 without overlapping the first connection electrode CE1. Further, the first contact hole CH1 may be irradiated with laser beams, such that the connection portion of the first contact hole CH1, which connects the first reflective electrode RE1 and the driving transistor DT, may be destroyed. Therefore, as the connection portion between the first reflective electrode RE1 and the driving source electrode DSE is damaged, the driving transistor DT and the light-emitting element 120 may be separated, and a bright spot defect may be suppressed.

Meanwhile, FIG. 5B illustrates the area, in which the first connection electrode CE1 and the repair line WRL are formed, but does not illustrate the first contact hole CH1. However, as illustrated in FIG. 5A, the first contact hole CH1 may be present in an area in which the first connection electrode CE1 and the repair line WRL are not formed.

Next, with reference to FIG. 6, the welding process of connecting the repair line WRL and the first reflective electrode RE1 by irradiating the welding area WA with laser beams may be performed. For example, when a defect occurs on any one of the pair of first sub pixels SP1, the first contact hole CH1 of the defective sub pixel SP may be destroyed, and then the welding area WA formed in any one of the pair of first sub pixels SP1 may be irradiated with laser beams.

In the welding area WA, an end of the repair line WRL and the first reflective electrode RE1 are disposed to overlap each other with the third planarization layer 115c, the second planarization layer 115b, the bonding layer AD, and the third passivation layer 114c interposed therebetween. When the welding area WA is irradiated with laser beams, the third planarization layer 115c, the second planarization layer 115b, the bonding layer AD, and the third passivation layer 114c may be destroyed, such that the repair line WRL and the first reflective electrode RE1 may be connected to each other. The insulation layers between the repair line WRL and the first reflective electrode RE1 may be destroyed in an atypical shape, such that the first reflective electrode RE1 and the repair line WRL may be electrically connected to each other. Therefore, after the welding process, the first connection electrode CE1 of the defective sub pixel SP and the first connection electrode CE1 of the normal sub pixel SP may be electrically connected to each other through the repair line WRL and the first reflective electrode RE1.

Therefore, the driving transistor DT of the normal sub pixel SP may be electrically connected to both the first connection electrode CE1 of the normal sub pixel SP and the first connection electrode CE1 of the defective sub pixel SP, and the light-emitting element 120 of the defective sub pixel SP and the light-emitting element 120 of the normal sub pixel SP may be connected in parallel to the driving transistor DT of the normal sub pixel SP. Therefore, the light-emitting element 120 of the defective sub pixel SP and the light-emitting element 120 of the normal sub pixel SP may be connected in parallel to the pixel circuit of the normal sub pixel SP and operate together.

Therefore, in the display device 100 according to the embodiment of the present disclosure, the plurality of sub pixels SP, which constitutes one pixel PX, is disposed to be symmetric horizontally with respect to the scan line SL, such that the plurality of repair lines WRL may be formed so as not to overlap one another. For example, the repair line WRL, which connects the pair of first sub pixels SP1 closest in distance to each other, may be disposed to be closest to the reference line RL. Further, the repair line WRL, which connects the pair of third sub pixels SP3 farthest in distance from each other, may be disposed to be farthest from the reference line RL. The repair line WRL, which connects the pair of second sub pixels SP2, may be disposed between the repair line WRL, which connects the first sub pixels SP1, and the repair line WRL that connects the third sub pixels SP3. Therefore, the repair line WRL, which connects the third sub pixels SP3, may be disposed to surround the repair line WRL that connects the first sub pixel SP1 and the second sub pixel SP2. The repair line WRL, which connects the second sub pixels SP2, may be disposed to surround the repair line WRL that connects the first sub pixels SP1. Therefore, the repair line WRL, which connects the sub pixels SP closest in distance to each other, may have a shorter length, and the repair line WRL, which connects the sub pixels SP farthest in distance from each other, may have a longer length.

Therefore, the positions of the repair lines WRL, which connect the plurality of sub pixels SP, do not overlap one another, such that the repair lines WRL may be configured as a single layer on the same layer. If the routes of the repair lines WRL overlap one another, some of the repair lines WRL need to be substituted with conductive layers on other layers in order to suppress interference between the repair lines WRL. In this case, the repair lines WRL need to be configured as a plurality of conductive layers disposed on different layers, which may complicate the design of the repair lines WRL and the sub pixels SP. However, in the display device 100 according to the embodiment of the present disclosure, the repair line WRL, which connects the pair of sub pixels SP far in distance from each other, may be disposed to surround the repair line WRL that connects the pair of sub pixels SP close in distance to each other, such that the two repair lines WRL may be inhibited from interfering with each other, and the repair lines WRL may be formed as a single conductive layer on the same layer.

In addition, in the display device 100 according to the embodiment of the present disclosure, the plurality of sub pixels SP may be disposed to be symmetric horizontally, which may suppress interference between the plurality of repair lines WRL. If the plurality of sub pixels SP is not disposed to be symmetric horizontally, at least some of the routes between the plurality of repair lines WRL inevitably overlap one another. For example, if the plurality of sub pixels SP are disposed in the order of the first sub pixel SP1, the second sub pixel SP2, the third sub pixel SP3, the first sub pixel SP1, the second sub pixel SP2, and the third sub pixel SP3 in one pixel area UPA, the repair line WRL, which connects the second sub pixels SP2, and the repair line WRL, which connects the pair of first sub pixels SP1, inevitably overlap each other once or more times. That is, in order to connect one pair of sub pixels SP, one repair line WRL needs to unconditionally pass through the repair line WRL that connects the other pair of sub pixels SP. Therefore, the repair lines WRL need to be formed as a plurality of conductive layers to suppress interference at the point at which the repair lines WRL overlap one another. In contrast, according to the display device 100 according to the embodiment of the present disclosure, the plurality of sub pixels SP is disposed to be symmetric horizontally, such that one repair line WRL, which connects the sub pixels SP, may be disposed to surround another repair line WRL, and the plurality of repair lines WRL may be disposed so as not to overlap one another. Therefore, the routes between the plurality of repair lines WRL may be designed so as not to overlap one another, such that the plurality of repair lines WRL may be formed as a single layer on the same layer. Therefore, the structures of the plurality of repair lines WRL may be simplified, and the decrease in transmittance rate of the transmissive area TA, which is caused by the repair lines WRL, may be reduced or minimized.

Further, in the display device 100 according to the embodiment of the present disclosure, the plurality of repair lines WRL is formed as a single layer made of a transparent conductive material, thereby reducing or minimizing the decrease in transmittance rate caused by the plurality of repair lines WRL. For example, the first connection electrode CE1 and the second connection electrode CE2 may be made of a transparent conductive material so that the first connection electrode CE1 and the second connection electrode CE2 may transmit the light, which is emitted from the light-emitting element 120, to the outside of the display device 100. Further, in case that the repair lines WRL are formed by the same process as the first connection electrode CE1, the repair lines WRL may be formed as a single-layer structure made of a transparent conductive material. The plurality of repair lines WRL may connect the plurality of sub pixels SP at the outermost periphery of the pixel area UPA. That is, at least some of the plurality of repair lines WRL may be disposed in the transmissive area TA. In this case, because the plurality of repair lines WRL is made of only a transparent conductive material, the decrease in transmittance rate caused by the plurality of repair lines WRL may be reduced or minimized. In addition, as described above, the plurality of sub pixels SP is disposed to be symmetric horizontally, such that the plurality of repair lines WRL may be formed as a single-layer structure made of a transparent conductive material. Therefore, in the display device 100 according to the embodiment of the present disclosure, the plurality of repair lines WRL is made of only a transparent conductive material, such that the decrease in transmittance rate caused by the plurality of repair lines WRL may be reduced or minimized.

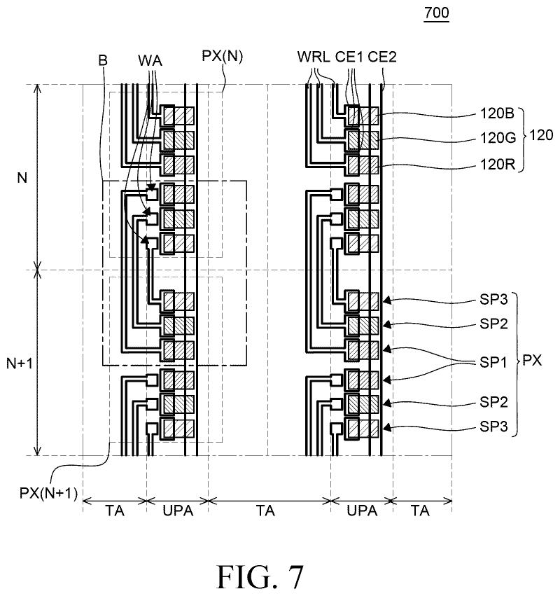

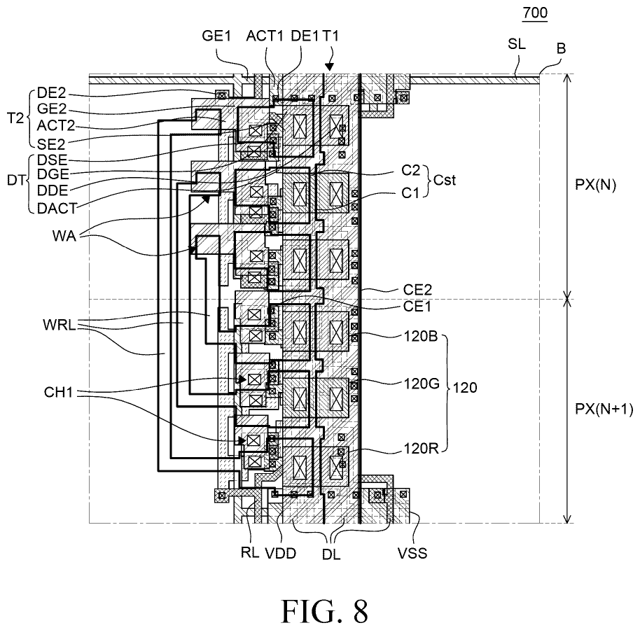

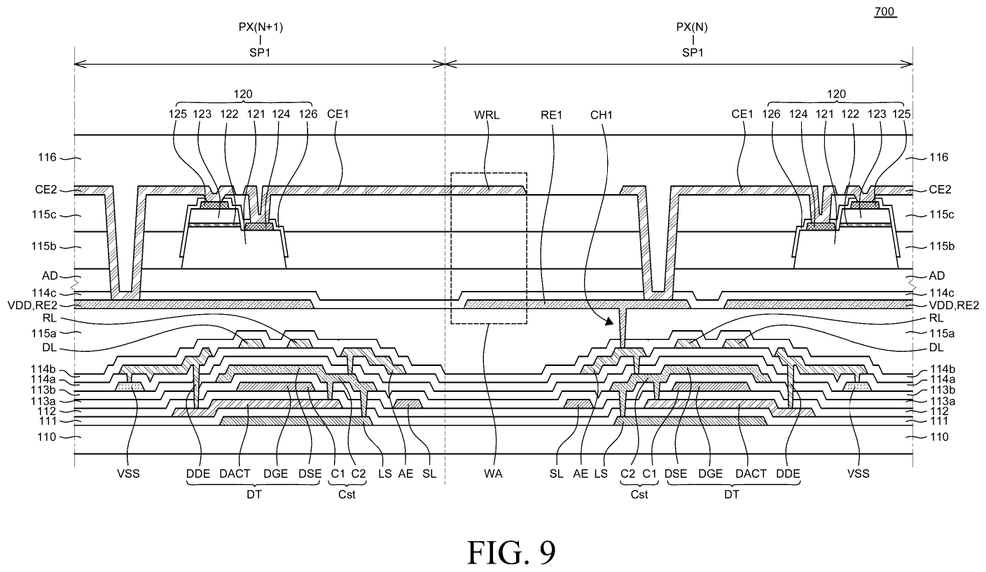

FIG. 7 is a schematic enlarged top plan view of a display area of a display device according to another embodiment of the present disclosure. FIG. 8 is an enlarged top plan view of area B in FIG. 7. FIG. 9 is a cross-sectional view of a pair of sub pixels of the display device according to another embodiment of the present disclosure. A display device 700 illustrated in FIGS. 7 to 9 is substantially identical in configuration to the display device 100 illustrated in FIGS. 1 to 6, except for a connection relationship between the repair lines WRL. Therefore, repeated descriptions of the identical components will be omitted.

With reference to FIGS. 7 and 8, the repair line WRL is disposed between the pixels PX adjacent to each other in the column direction. For example, the plurality of pixel areas UPA may be disposed in a plurality of rows and a plurality of columns. The repair lines WRL may be disposed on the same column and disposed between the pixel areas UPA disposed in the adjacent rows.

For example, the repair line WRL may be disposed to connect the sub pixel SP, which is disposed at the other side of the scan line SL among the plurality of sub pixels SP of the pixel PX(N) disposed in the Nth row, and the sub pixel SP that is disposed at one side of the scan line SL among the plurality of sub pixels SP of the pixel PX(N+1) disposed in the (N+1)th row. That is, when a defect occurs, the plurality of sub pixels SP, which is disposed at the other side of the scan line SL, may be connected to the plurality of sub pixels SP in the pixel area UPA in the next row, through the repair lines WRL. Further, the plurality of sub pixels SP, which is disposed at one side of the scan line SL, may be connected to the plurality of sub pixels SP in the pixel area UPA in the previous row, through the repair lines WRL.

One end of each of the plurality of repair lines WRL may be disposed to overlap the first reflective electrode RE1 of each of the plurality of sub pixels SP in the pixel area UPA in the Nth row. The other end of each of the plurality of repair lines WRL may be connected to the first connection electrode CE1 of each of the plurality of sub pixels SP in the pixel area UPA in the (N+1)th row. In this case, the welding area WA, which is to be irradiated with laser beams, is an area in which the first reflective electrode RE1 and one end of the repair line WRL overlap, and the welding area WA may be disposed in the pixel area UPA in the Nth row. That is, the welding area WA may be formed in any one of the pixel area UPA in the Nth row and the pixel area UPA in the (N+1)th row.

However, one end of the repair line WRL may be connected to the first connection electrode CE1 in the pixel area UPA in the Nth row, and the other end of the repair line WRL may be disposed to overlap the first reflective electrode RE1 in the (N+1)th row, such that the welding area WA may be formed in the pixel area UPA in the (N+1)th row. However, the arrangement of the welding area WA is not limited thereto.

In this case, the plurality of sub pixels SP in the adjacent pixel areas UPA may also be disposed to be symmetric horizontally with respect to the boundary between the pixel areas UPA. For example, the sub pixels SP, which are disposed at the other side of the scan line SL among the plurality of sub pixels SP in the Nth row, may be disposed in the order of the first sub pixel SP1, the second sub pixel SP2, and the third sub pixel SP3 from above. The sub pixels SP, which are disposed at one side of the scan line SL among the plurality of sub pixels SP in the (N+1)th row, may be disposed in the order of the third sub pixel SP3, the second sub pixel SP2, and the first sub pixel SP1 from above. Therefore, the plurality of sub pixels SP are disposed to be symmetric horizontally with respect to the boundary between the pixel areas UPA, such that the plurality of repair lines WRL may be formed so as not to overlap one another.

Therefore, in the display device 700 according to another embodiment of the present disclosure, the plurality of repair lines WRL may be formed between the adjacent pixel areas UPA, and the repair process may be performed. For example, in case that some of the sub pixels SP included in one pixel area UPA are defective, the repair line WRL may be used to electrically connect the light-emitting element 120 of the defective sub pixel SP to the pixel circuit of the sub pixel SP in the adjacent pixel area UPA. If both the pair of sub pixels SP, which are the same type and included in one pixel area UPA, are defective, the repair process may be performed by connecting the pair of sub pixels SP to the sub pixels SP in the different pixel areas UPA, which may improve the yield of the repair process.

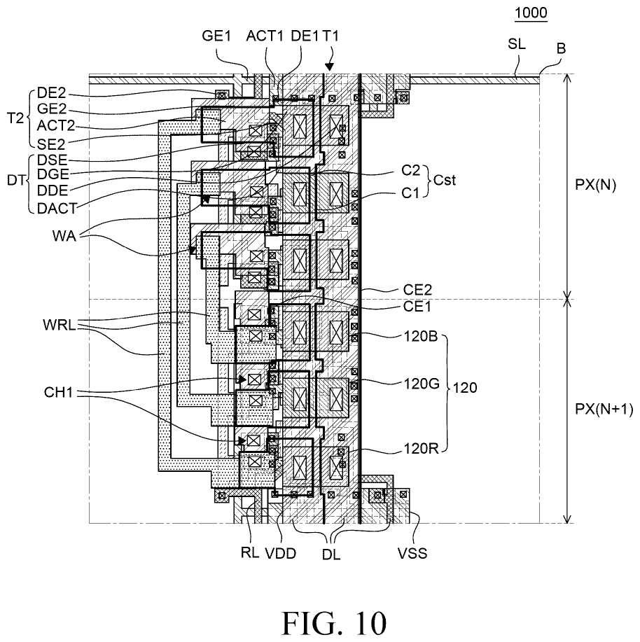

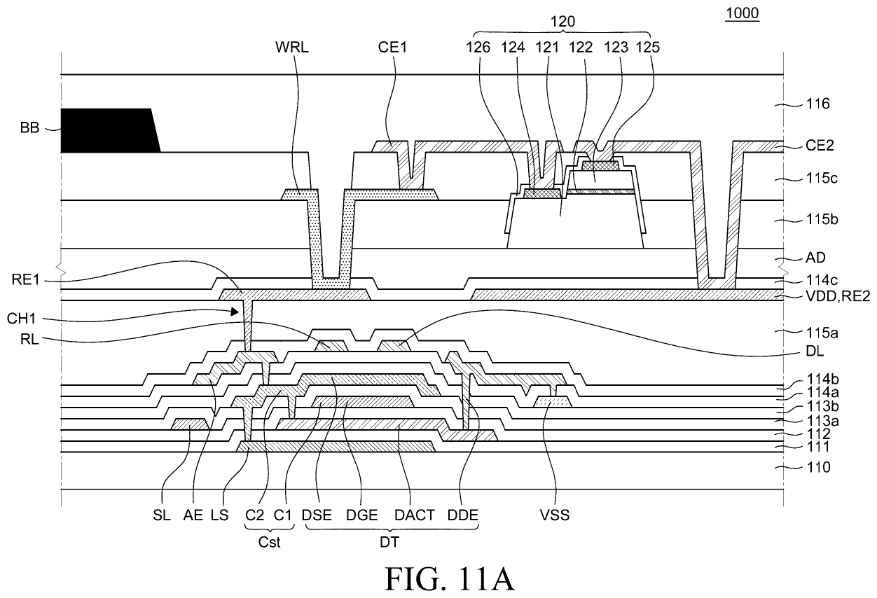

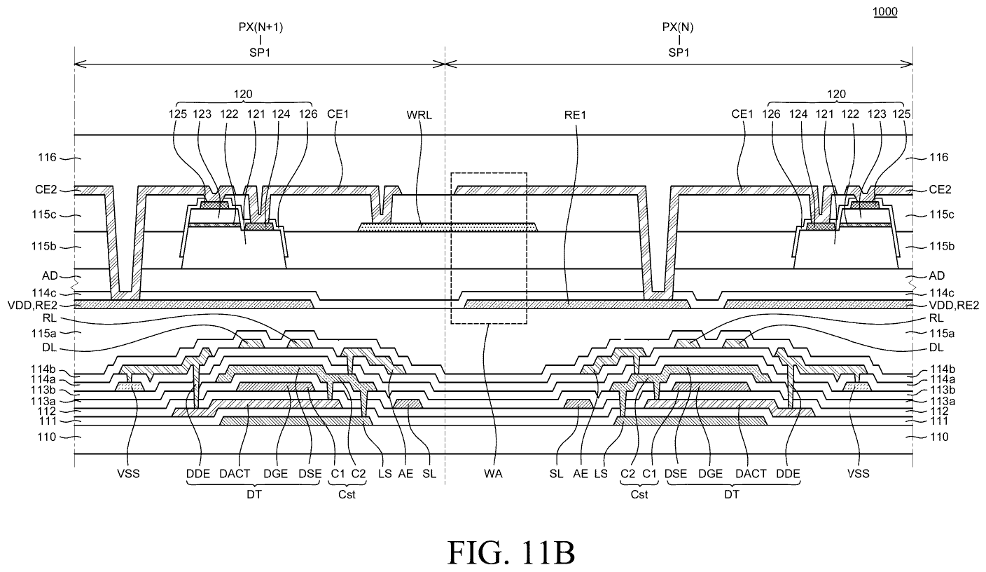

FIG. 10 is an enlarged top plan view of a display device according to still another embodiment of the present disclosure. FIGS. 11A and 11B are cross-sectional views of sub pixels of the display device according to still another embodiment of the present disclosure. A display device 1000 illustrated in FIGS. 10 to 11B is substantially identical in configuration to the display device 700 illustrated in FIGS. 7 to 9, except for the repair lines WRL. Therefore, repeated descriptions of the identical components will be omitted. Meanwhile, for convenience of description, FIG. 11B illustrates only a part of the first reflective electrode RE1 that overlaps the first connection electrode CE1, but FIG. 11B does not illustrate the first contact hole CH1 between the driving source electrode DSE and the first reflective electrode RE1 that does not overlap the first connection electrode CE1. However, as described above with reference to FIG. 5A, the first contact hole CH1, through which the first reflective electrode RE1 and the driving source electrode DSE are connected, may be formed in the area in which the first connection electrode CE1 is not disposed.

With reference to FIGS. 10 to 11B, the plurality of repair lines WRL is disposed between the second planarization layer 115b and the third planarization layer 115c. The plurality of repair lines WRL may be disposed between the second planarization layer 115b and the third planarization layer 115c and disposed between the first connection electrodes CE1 of the pair of sub pixels SP. The plurality of repair lines WRL may be made of a transparent conductive material such as indium tin oxide (ITO) or indium zinc oxide (IZO).

One end of each of the plurality of repair lines WRL may be disposed in the pixel area UPA in the Nth row and disposed to overlap the first reflective electrode RE1 and the first connection electrode CE1 of each of the plurality of sub pixels SP. That is, an area, in which one end of each of the plurality of repair lines WRL is disposed, may be defined as the welding area WA that is to be irradiated with laser beams.

If the defective sub pixel SP does not occur, one end of each of the plurality of repair lines WRL may be disposed to overlap the first reflective electrode RE1 and the first connection electrode CE1 of each of the plurality of sub pixels SP in the pixel area UPA in the Nth row, whereas the plurality of repair lines WRL may be separated from the first reflective electrode RE1 and the first connection electrode CE1 with the third planarization layer 115c, the second planarization layer 115b, the bonding layer AD, and the third passivation layer 114c interposed the plurality of repair lines WRL and the first reflective electrode RE1, and between the plurality of repair lines WRL and the first connection electrode CE1.

In contrast, in case that the defective sub pixel SP occurs, the welding area WA disposed at one end of each of the plurality of repair lines WRL may be irradiated with laser beams, such that the plurality of repair lines WRL may be connected to at least any one of the first connection electrode CE1 above the repair line WRL and the first reflective electrode RE1 below the repair line WRL. For example, the laser beams may destroy the third planarization layer 115c between the first connection electrode CE1 and the repair line WRL, and the third planarization layer 115c may be removed, such that the first connection electrode CE1 and the repair line WRL may be connected to each other. Further, the second planarization layer 115b, the bonding layer AD, and the third passivation layer 114c between the repair line WRL and the first reflective electrode RE1 may also be destroyed by the laser beams, such that the repair line WRL and the first reflective electrode RE1 may be connected to each other. Therefore, the welding process may be performed in the welding area WA, such that the repair line WRL may be electrically connected to the first connection electrode CE1 and the first reflective electrode RE1.

Further, the other end of each of the plurality of repair lines WRL may be disposed in the pixel area UPA in the (N+1)th row, electrically connected to the first connection electrode CE1 of each of the plurality of sub pixels SP through the third planarization layer 115c, and simultaneously, electrically connected to the first reflective electrode RE1 through the contact holes of the second planarization layer 115b, the bonding layer AD, and the third passivation layer 114c. That is, the plurality of repair lines WRL may electrically connect the first connection electrodes CE1 and the first reflective electrodes RE1 in the plurality of sub pixels SP in the pixel area UPA in the (N+1)th row.

Meanwhile, the structure of the repair line WRL illustrated in FIGS. 10 to 11B may also be applied to the display device 100 in FIGS. 1 to 6 in which the repair line WRL is disposed in one pixel area UPA. However, the present disclosure is not limited thereto.

Therefore, in the display device 1000 according to still another embodiment of the present disclosure, the first connection electrode CE1, the repair line WRL, and the first reflective electrode RE1 are disposed to overlap one another in the welding area WA, thereby reducing or minimizing a defect in which the repair line WRL is not connected. The repair line WRL may be disposed between the first connection electrode CE1 and the first reflective electrode RE1 in the welding area WA. Even if the intensity of laser beams is low and the second planarization layer 115b, the bonding layer AD, and the third passivation layer 114c disposed below the repair line WRL are not at least partially removed, the repair line WRL and the first connection electrode CE1 disposed above the repair line WRL may be connected to each other, thereby reducing or minimizing the defect in which the repair line WRL is not connected. In addition, only one third planarization layer 115c, instead of a plurality of insulation layers, is disposed between the repair line WRL and the first connection electrode CE1, such that the third planarization layer 115c may be more easily removed, and the repair line WRL and the first connection electrode CE1 may be easily connected, during the welding process. Therefore, in the welding area WA, the first connection electrode CE1, the repair line WRL, and the first reflective electrode RE1 are disposed in the form of a three-layer structure, such that the repair line WRL may be more easily connected to at least any one of the first connection electrode CE1 and the first reflective electrode RE1 during the welding process, which may improve the yield of the repair process.

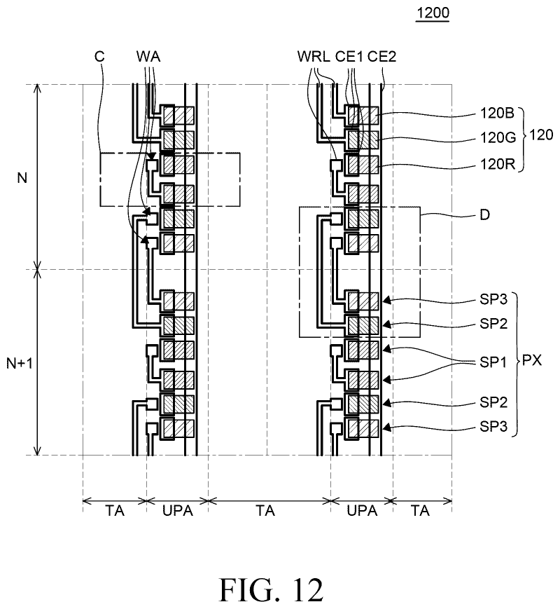

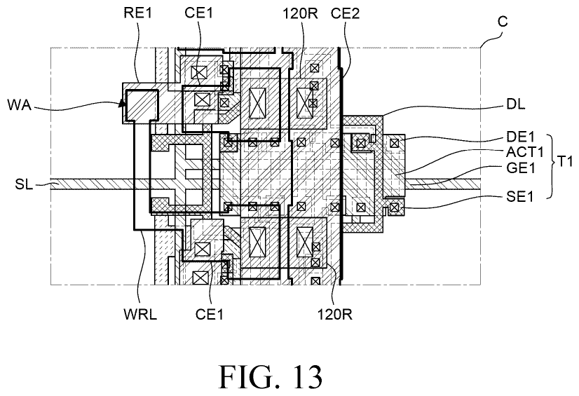

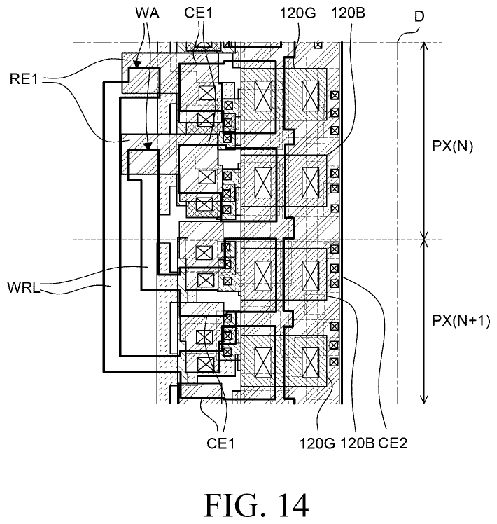

FIG. 12 is a schematic enlarged top plan view of the display device according to yet another embodiment of the present disclosure. FIG. 13 is an enlarged top plan view of area C in FIG. 12. FIG. 14 is an enlarged top plan view of area D in FIG. 12. A display device 1200 illustrated in FIGS. 12 to 14 is substantially identical in configuration to the display devices 100 and 700 illustrated in FIGS. 1 to 9, except for a connection relationship between the repair lines WRL. Therefore, repeated descriptions of the identical components will be omitted.

With reference to FIG. 12, the plurality of sub pixels SP may be repaired by using different sub pixels SP disposed in the same pixel area UPA or using the sub pixels SP disposed in the adjacent pixel areas UPA. That is, the plurality of repair lines WRL may be disposed between the pair of sub pixels SP disposed in the same pixel area UPA or between the pair of sub pixels SP disposed in the different pixel areas UPA.

For example, with reference to FIGS. 12 and 13, in one pixel area UPA, the repair line WRL may be disposed between the pair of first sub pixels SP1 closest in distance to each other. That is, the first sub pixel SP1 may be repaired by using the other first sub pixel SP1 disposed in the same pixel area UPA.

As another example, with reference to FIGS. 12 and 14, one repair line WRL may be disposed between the second sub pixel SP2 in one pixel area UPA and the second sub pixel SP2 in another pixel area UPA adjacent to one pixel area UPA. When the defective sub pixel SP occurs, the repair line WRL may be used to connect the second sub pixels SP2 disposed in the different pixel areas UPA. Further, the repair line WRL may be disposed between the third sub pixel SP3 in one pixel area UPA and the third sub pixel SP3 of another pixel area UPA adjacent to one pixel area UPA. When the defective sub pixel SP occurs, the repair line WRL may be used to connect the third sub pixels SP3 disposed in the different pixel areas UPA.

Meanwhile, the drawings illustrate that the repair line WRL is disposed between the second sub pixels SP2 in the different pixel areas UPA. However, the repair line WRL may be disposed between the second sub pixels SP2 in the same pixel area UPA. However, the present disclosure is not limited thereto.

In the display device 1200 according to yet another embodiment of the present disclosure, the repair line WRL may be disposed in consideration of a distance between the plurality of sub pixels SP. The repair line WRL may be connected between the pair of sub pixels SP close in distance to each other, such that a length of the repair line WRL may be reduced. For example, the repair line WRL may be disposed between the first sub pixels SP1 relatively close in distance to each other among the plurality of sub pixels SP disposed in the same pixel area UPA. That is, a distance from one first sub pixel SP1 to the first sub pixel SP1 in the same pixel area UPA is much shorter than a distance from one first sub pixel SP1 to the first sub pixel SP1 in another pixel area UPA. Therefore, the repair line WRL with the shortest length may be formed between the pair of first sub pixels SP1 disposed in the same pixel area UPA. In contrast, a distance from one third sub pixel SP3 to the third sub pixel SP3 in another adjacent pixel area UPA is shorter than a distance from one third sub pixel SP3 to the third sub pixel SP3 in the same pixel area UPA. Therefore, the repair line WRL may be disposed between the third sub pixels SP3 disposed in the different pixel areas UPA, such that the length of the repair line WRL may be reduced. In addition, in accordance with design, the second sub pixel SP2 may be connected to another second sub pixel SP2 disposed in the same pixel area UPA or connected to the second sub pixel SP2 in another adjacent pixel area UPA. Therefore, the repair line WRL may be disposed between the sub pixels SP disposed in the same pixel area UPA or the two adjacent pixel areas UPA in consideration of the distance between the plurality of sub pixels SP, such that the length of the repair line WRL may be reduced. Therefore, the reduction in length of the repair line WRL may reduce the resistance of the repair line WRL and reduce the power consumption, such that the display device 1200 may operate with low power consumption.

The exemplary embodiments of the present disclosure can also be described as follows:

According to an aspect of the present disclosure, a display device includes a substrate configured to define a plurality of pixel areas disposed to be spaced apart from each other, and a plurality of transmissive areas disposed between the plurality of pixel areas, a plurality of pixels disposed in the plurality of pixel areas and each including a plurality of sub pixels, and a plurality of repair lines disposed between the plurality of sub pixels and made of a transparent conductive material. The plurality of repair lines are disposed on the same layer and spaced apart from each other.

The display device may further include at least some of the plurality of repair lines overlap the plurality of transmissive areas.

The display device may further include a plurality of scan lines extending in a row direction and disposed to traverse the plurality of pixel areas. The plurality of pixels each may include a pair of first sub pixels disposed to be symmetric horizontally with respect to the plurality of scan lines, a pair of second sub pixels disposed to be symmetric horizontally with respect to the plurality of scan lines, and a pair of third sub pixels disposed to be symmetric horizontally with respect to the plurality of scan lines, and among the plurality of sub pixels, the pair of first sub pixels may be disposed to be closest to the plurality of scan lines, and the pair of third sub pixels may be disposed to be farthest from the plurality of scan lines.

The plurality of repair lines may be disposed between the pair of first sub pixels, between the pair of second sub pixels, and between the pair of third sub pixels, and the repair line, which is disposed between the pair of third sub pixels among the plurality of repair lines, may be disposed to surround the repair line disposed between the pair of first sub pixels and the repair line disposed between the pair of second sub pixels.

One end and the other end of each of the plurality of repair lines may be disposed in the same pixel area among the plurality of pixel areas.

One end of each of the plurality of repair lines may be disposed in one pixel area among the plurality of pixel areas, and the other end of each of the plurality of repair lines may be disposed in a pixel area adjacent to one pixel area.

One end and the other end of some of the plurality of repair lines may be disposed in the same pixel area among the plurality of pixel areas, and one end and the other end of the remaining repair lines may be disposed in different pixel areas among the plurality of pixel areas.

The display device may further include a first reflective electrode disposed in each of the plurality of sub pixels and disposed on the substrate, a light-emitting element disposed in each of the plurality of sub pixels, disposed on the first reflective electrode, and including a first electrode, a planarization layer disposed on the light-emitting element, and a first connection electrode disposed on the planarization layer and electrically connected to the first electrode and the first reflective electrode.

One end of each of the plurality of repair lines may overlap the first reflective electrode of each of any one of the pair of first sub pixels, any one of the pair of second sub pixels, and any one of the pair of third sub pixels, and the other end of each of the plurality of repair lines may be connected to the first connection electrode of each of the other of the pair of first sub pixels, the other of the pair of second sub pixels, and the other of the pair of third sub pixels.

One end of each of the plurality of repair lines may be connected to the first reflective electrode in some of the plurality of sub pixels, and one end of each of the plurality of repair lines may be separated from the first reflective electrode in some of the remaining sub pixels.

The plurality of repair lines may be disposed on the same layer as the first connection electrode and integrated with the first connection electrode.

The display device may further include a bonding layer disposed between the first reflective electrode and the light-emitting element. The plurality of repair lines may be disposed on the bonding layer and disposed between the first reflective electrode and the first connection electrode.

One end of each of the plurality of repair lines may overlap the first connection electrode of each of any one of the pair of first sub pixels, any one of the pair of second sub pixels, and any one of the pair of third sub pixels, and the other end of each of the plurality of repair lines may be connected to the first connection electrode of each of the other of the pair of first sub pixels, the other of the pair of second sub pixels, and the other of the pair of third sub pixels through a contact hole of the planarization layer.

One end of each of the plurality of repair lines may be connected to at least any one of the first reflective electrode and the first connection electrode in some of the plurality of sub pixels, and one end of each of the plurality of repair lines may be separated from the first reflective electrode and the first connection electrode in some of the remaining sub pixels.

The first reflective electrode in each of the plurality of sub pixels may include a portion that overlaps the first connection electrode, and a portion that does not overlap the first connection electrode.

The display device may further include a driving transistor disposed between the substrate and the first reflective electrode in each of the plurality of sub pixels, and an insulation layer disposed between the driving transistor and the first reflective electrode. The first reflective electrode may be electrically connected to the driving transistor through a first contact hole of the insulation layer, and the first contact hole may overlap the portion of the first reflective electrode that does not overlap the first connection electrode.

The display device may further include a plurality of data lines extending in a column direction on the substrate. The plurality of pixel areas may overlap an area in which the plurality of data lines is disposed.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

1. A display device comprising:
a substrate having thereon a plurality of pixel areas and a plurality of transmissive areas, the plurality of pixel areas disposed to be spaced apart from each other, and the plurality of transmissive areas disposed between the plurality of pixel areas;
a plurality of pixels disposed in the plurality of pixel areas, the plurality of pixels each including a plurality of sub pixels; and
a plurality of repair lines disposed between the plurality of sub pixels, the plurality of repair lines including a transparent conductive material,
wherein the plurality of repair lines is disposed on a same layer and spaced apart from each other.

2. The display device of claim 1, further comprising:
at least some of the plurality of repair lines overlap the plurality of transmissive areas from a plan view.

3. The display device of claim 1, further comprising:
a plurality of scan lines extending in a row direction and disposed to traverse the plurality of pixel areas,
wherein the plurality of pixels each comprises:
a pair of first sub pixels disposed to be symmetric horizontally with respect to the plurality of scan lines;
a pair of second sub pixels disposed to be symmetric horizontally with respect to the plurality of scan lines; and
a pair of third sub pixels disposed to be symmetric horizontally with respect to the plurality of scan lines, and
wherein among the plurality of sub pixels, the pair of first sub pixels is disposed to be closest to the plurality of scan lines, and the pair of third sub pixels is disposed to be farthest from the plurality of scan lines.

4. The display device of claim 3, wherein the plurality of repair lines are disposed between the pair of first sub pixels, between the pair of second sub pixels, and between the pair of third sub pixels, and
wherein the repair line, which is disposed between the pair of third sub pixels among the plurality of repair lines, is disposed to surround the repair line disposed between the pair of first sub pixels and the repair line disposed between the pair of second sub pixels.

5. The display device of claim 3, wherein one end and the other end of each of the plurality of repair lines are disposed in the same pixel area among the plurality of pixel areas.

6. The display device of claim 3, wherein one end of each of the plurality of repair lines are disposed in one pixel area among the plurality of pixel areas, and the other end of each of the plurality of repair lines are disposed in a pixel area adjacent to one pixel area.

7. The display device of claim 3, wherein one end and the other end of some of the plurality of repair lines are disposed in the same pixel area among the plurality of pixel areas, and one end and the other end of the remaining repair lines are disposed in different pixel areas among the plurality of pixel areas.

8. The display device of claim 3, further comprising:
a first reflective electrode disposed in each of the plurality of sub pixels and disposed on the substrate;
a light-emitting element disposed in each of the plurality of sub pixels, disposed on the first reflective electrode, and including a first electrode;
a planarization layer disposed on the light-emitting element; and
a first connection electrode disposed on the planarization layer and electrically connected to the first electrode and the first reflective electrode.

9. The display device of claim 8, wherein one end of each of the plurality of repair lines overlaps the first reflective electrode of each of any one of the pair of first sub pixels, any one of the pair of second sub pixels, and any one of the pair of third sub pixels, and
wherein the other end of each of the plurality of repair lines are connected to the first connection electrode of each of the other of the pair of first sub pixels, the other of the pair of second sub pixels, and the other of the pair of third sub pixels.

10. The display device of claim 9, wherein one end of each of the plurality of repair lines are connected to the first reflective electrode in some of the plurality of sub pixels, and wherein one end of each of the plurality of repair lines are separated from the first reflective electrode in some of the remaining sub pixels.

11. The display device of claim 9, wherein the plurality of repair lines are disposed on a same layer as the first connection electrode and integrated with the first connection electrode.

12. The display device of claim 9, further comprising:
a bonding layer disposed between the first reflective electrode and the light-emitting element,
wherein the plurality of repair lines are disposed on the bonding layer and disposed between the first reflective electrode and the first connection electrode.

13. The display device of claim 12, wherein one end of each of the plurality of repair lines overlaps the first connection electrode of each of any one of the pair of first sub pixels, any one of the pair of second sub pixels, and any one of the pair of third sub pixels, and
wherein the other end of each of the plurality of repair lines are connected to the first connection electrode of each of the other of the pair of first sub pixels, the other of the pair of second sub pixels, and the other of the pair of third sub pixels through a contact hole of the planarization layer.

14. The display device of claim 13, wherein one end of each of the plurality of repair lines are connected to at least any one of the first reflective electrode and the first connection electrode in some of the plurality of sub pixels, and
wherein one end of each of the plurality of repair lines are separated from the first reflective electrode and the first connection electrode in some of the remaining sub pixels.

15. The display device of claim 8, wherein the first reflective electrode in each of the plurality of sub pixels includes a portion that overlaps the first connection electrode, and a portion that does not overlap the first connection electrode.

16. The display device of claim 15, further comprising:
a driving transistor disposed between the substrate and the first reflective electrode in each of the plurality of sub pixels; and
an insulation layer disposed between the driving transistor and the first reflective electrode,
wherein the first reflective electrode is electrically connected to the driving transistor through a first contact hole of the insulation layer, and
wherein the first contact hole overlaps the portion of the first reflective electrode that does not overlap the first connection electrode.

17. The display device of claim 1, further comprising:
a plurality of data lines extending in a column direction on the substrate,
wherein the plurality of pixel areas overlaps an area in which the plurality of data lines is disposed.

18. A display device comprising:
a substrate having thereon a first sub pixel and a second sub pixel adjacent to the first sub pixel;
a first light emitting element included in the first sub pixel, the first light emitting element including:
a first electrode; and
a second electrode adjacent to the first electrode;
a second light emitting element included in the second sub pixel;
a thin film transistor electrically connected to the second light emitting element in the second sub pixel;
a reflective electrode between the thin film transistor and the second light emitting element in the second sub pixel, the reflective electrode electrically connecting the thin film transistor and the second light emitting element;
a connection electrode extending from the first sub pixel to the second sub pixel, the connection electrode electrically connected to either the first electrode or the second electrode of the first light emitting element; and
a repair line having a first end and a second end opposite the first end, the first end of the repair line extending from the connection electrode in the first sub pixel and the second end of the repair line extending toward the second sub pixel,
wherein the second end of the repair line overlaps the reflective electrode in the second sub pixel from a plan view.

19. The display device of claim 18, wherein the repair line continuously and contiguously extends from the connection electrode and is disposed on a same layer as the connection electrode.

20. The display device of claim 18, wherein the repair line extends from the connection electrode and is disposed on a different layer from the connection electrode, and wherein the repair line is between the connection electrode and reflective electrode.

21. The display device of claim 18, wherein the repair line is entirely made of a transparent conductive material.

22. The display device of claim 18, wherein the first sub pixel and the second sub pixel are a pair of a same type of sub pixels.

23. The display device of claim 18, wherein the repair line is configured to electrically and directly connect to the reflective electrode of the second sub pixel during a repair process.

24. The display device of claim 18, wherein, during a repair process, the repair line is electrically and directly connected to the reflective electrode of the second sub pixel and operatively connected to the thin film transistor of the second sub pixel to operate the first light emitting element based on the thin film transistor of the second sub pixel.
